(19) United States
(12) Patent Application Publication
(10) Pub. No.: US 2023/0269960 A1
(43) Pub. Date: Aug. 24, 2023

(54) SEALING STRUCTURE AND DISPLAY DEVICE HAVING THE SAME

(71) Applicant: Samsung Display Co., LTD., Yongin-si (KR)

(72) Inventors: SANGWOON JUNG, Yongin-si (KR); Seung Gil BAEK, Cheonan-si (KR); Kang-Yong LEE, Seoul (KR)

(21) Appl. No.: 17/874,556

(22) Filed: Jul. 27, 2022

(30) Foreign Application Priority Data
Feb. 21, 2022 (KR) 10-2022-0022237

(51) Int. Cl. H01L 51/52; H01L 27/32

(52) U.S. Cl. CPC H01L 51/524; H01L 27/3244; H01L 51/5284; H01L 51/5293

(57) ABSTRACT

A display panel includes a display area, a first substrate including a transistor in the display area, and a second substrate facing the first substrate, and a case member in which the display panel is accommodated. The case member including a bottom portion facing the first substrate and the second substrate of the display panel, and a first side portion protruding from the bottom portion and toward the display panel. The second substrate include a first portion corresponding to the first substrate, and a second portion extended from the first portion to overlap the first side portion of the case member.

This application claims priority to Korean Patent Application No. 10-2022-0022237, filed on Feb. 21, 2022, and all the benefits accruing therefrom under 35 U.S.C. §119, the entire contents of which are incorporated herein by reference.

### BACKGROUND

### (A) Field

The present disclosure relates to a display device.

### (B) Description of the Related Art

A display device includes a display panel including a substrate on which a thin film transistor, a light emitting device, etc. are formed. The display panel may further include a sealing substrate for protecting the light-emitting device.

The display device includes a case member for protecting and covering the display panel from the outside of the display panel.

### SUMMARY

Embodiments have been made in an effort to improve durability of a display device and provide a thin display device.

An embodiment of the invention provides a display device including a display panel configured to include a display area capable of displaying an image, and a case member configured to accommodate the display panel. The display panel includes a first substrate on which a plurality of transistors are formed (or provided), and a second substrate on the first substrate, the case member includes a bottom portion at a rear surface side of the first substrate, and a first side portion protruding upward from the bottom portion, the second substrate includes a first portion overlapping the first substrate and a second portion outside the first substrate without being overlapped therewith, and the second portion overlaps the first side portion in a plan view.

It may further include a plurality of light emitting devices formed on the first substrate, and a sealing portion between the first substrate and the second substrate. The second substrate and the sealing portion may seal the light emitting devices from the outside.

The second substrate may have a larger area than that of the first substrate, and an edge which is outside an edge of the first substrate.

A thickness of the second substrate may be equal to or greater than a thickness of the first substrate.

The first substrate and the second substrate may include glass.

It may further include a first adhesive member between the first side portion and the second portion of the second substrate.

The case member may further include a second side portion which further protrudes upward from an edge of the first side portion, and the second substrate may not overlap the second side portion in a plan view.

The second side portion may face a side surface of the second substrate.

The display device may further include a polarizer on an upper surface of the second substrate, and the polarizer may overlap the first substrate and the first portion of the second substrate in a plan view.

An edge of the polarizer may be aligned with an edge of the first substrate.

The display device may further include a printed layer positioned on an upper surface or a rear surface of an edge of the second substrate, and the printed layer may overlap an upper surface of the first side portion of the case member.

The display device may further include a sealing portion between the first substrate and the second substrate, and the printed layer may be on a rear surface of the second substrate and may not overlap the sealing portion.

The display device may further include a polarizer on an upper surface of the second substrate, and the printed layer may be on an upper surface of the second substrate and may not overlap the polarizer.

An embodiment of the invention provides a display device including a first substrate on which a plurality of transistors are formed, a second substrate on the first substrate, a sealing portion between the first substrate and the second substrate and configured to form a closed curve in a plan view, and a case member configured to have a bottom portion and a first side portion at an edge of the bottom portion, where a lower surface of an edge portion of the second substrate is fixed to an upper surface of the first side portion.

The second substrate may have a larger area than that of the first substrate, and an edge which is outside an edge of the first substrate.

A thickness of the second substrate may be equal to or greater than a thickness of the first substrate.

The case member may further include a second side portion which further protrudes upward from an edge of the first side portion, and the second substrate may not overlap the second side portion in a plan view.

The display device may further include a polarizer on an upper surface of the second substrate, and the polarizer may overlap the first substrate and the first portion of the second substrate in a plan view.

The display device may further include a printed layer on an upper surface or a rear surface of an edge of the second substrate, and the printed layer may overlap the first side portion of the case member.

An embodiment of the invention provides a display device including a display panel, and a case blocking member configured to include a bottom portion and a side portion. The display panel includes a first substrate, a second substrate, and a polarizer which are sequentially positioned on the bottom portion. An edge of the first substrate is spaced apart from the side portion, and an edge portion of the second substrate is positioned on the side portion to overlap the side portion.

According to the embodiments, it is possible to improve durability of a display device and provide a thin display device.

### BRIEF DESCRIPTION OF THE DRAWINGS

The above and other advantages and features of this disclosure will become more apparent by describing in further detail embodiments thereof with reference to the accompanying drawings, in which:

FIG. 1 illustrates a cross-sectional view of a display device according to an embodiment,

FIG. 2 illustrates a top plan view of a display device according to an embodiment,

FIGS. 3 to 8 each illustrate a cross-sectional view of a display device according to an embodiment, and

FIG. 9 illustrates a cross-sectional view of a sensor layer included in a display device according to an embodiment.

### DETAILED DESCRIPTION

The invention will be described more fully hereinafter with reference to the accompanying drawings, in which embodiments of the invention are shown. As those skilled in the art would realize, the described embodiments may be modified in various different ways, all without departing from the spirit or scope of the invention.

To clearly describe the invention, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the invention is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being related to another element such as being “on” another element, it can be directly on the other element or intervening elements may also be present. In contrast, when an element is referred to as being related to another element such as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. As used herein, a reference number may indicate a singular element or a plurality of the element. For example, a reference number labeling a singular form of an element within the drawing figures may be used to reference a plurality of the singular element within the text of specification “At least one” is not to be construed as limiting “a” or “an.” “Or” means “and/or.” As used herein, the term “and/or” includes any and all combinations of one or more of the associated listed items. In addition, unless explicitly described to the contrary, the word “comprise” and variations such as “comprises” or “comprising” will be understood to imply the inclusion of stated elements but not the exclusion of any other elements.

Furthermore, relative terms, such as “lower” or “bottom” and “upper” or “top,” may be used herein to describe one element’s relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Further, throughout the specification, the phrase “in a plan view” means when an object portion is viewed from above, and the phrase “in a cross-sectional view” means when a cross-section taken by vertically cutting an object portion is viewed from the side.

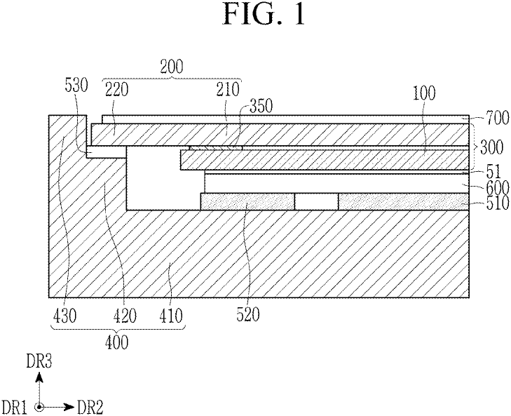

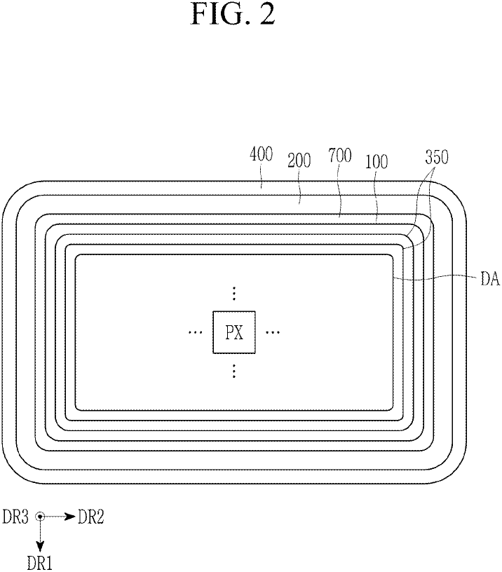

A display device according to an embodiment will now be described with reference to FIG. 1 and FIG. 2.

FIG. 1 illustrates a cross-sectional view of a display device according to an embodiment, and FIG. 2 illustrates a top plan view of a display device according to an embodiment.

Referring to FIG. 1 and FIG. 2, a display device according to an embodiment includes a display panel 300 and a case member 400.

The display panel 300 includes a display area DA that is an area (e.g., planar area) capable of displaying an image in a plan view. The display device and various components and layers thereof, such as the display area DA, may be disposed in a plane defined by a first direction DR1 and a second direction DR2 which cross each other. The display area DAmay include a pixel PX provided in plural including a plurality of pixels PX as units for generating and/or displaying an image (e.g., a display element). A thickness direction of the display device and various components or layers thereof may be defined along a third direction DR3 which crosses each of the first direction DR1 and the second direction DR2, without being limited thereto.

The display panel 300 may include a liquid crystal display and an organic light emitting diode display, without being limited thereto.

The display panel 300 includes a first substrate 100 and a second substrate 200 that face and overlap each other in (or along) a third direction DR3 in a cross-sectional view of the third direction DR3 illustrated in FIG. 1.

A plurality of signal lines, a plurality of transistors, a plurality of pixel electrodes, etc. may be positioned on the first substrate 100. A pixel electrode may be electrically connected to at least one transistor.

For example, when the display panel 300 is an emissive display device, a plurality of light emitting devices may be positioned on the first substrate 100.

A light emitting device may include a pixel electrode together with a common electrode and at least one emission layer which is positioned between the pixel electrode and the common electrode. The emission layer may be an organic emission layer including an organic light emitting material or an inorganic emission layer including an inorganic light emitting material.

One pixel electrode may be positioned in each pixel PX, but the invention is not limited thereto.

The second substrate 200 is positioned above the first substrate 100 in the cross-sectional view illustrated in FIG. 1. The second substrate 200 may seal an electric element such as a transistor and a light emitting device formed (or provided) on the first substrate 100 from the outside (e.g., outside of the display device or display panel 300) to protect the electric element and the light emitting device.

The first substrate 100 and the second substrate 200 may include an insulating material such as glass.

A sealing portion 350 may be positioned between the first substrate 100 and the second substrate 200. The sealing portion 350 may attach the first substrate 100 and the second substrate 200 to each other, and may seal a space defined between the first substrate 100 and the second substrate 200 together with the sealing portion 350, from the outside to prevent impurities such as moisture from penetrating between the first substrate 100 and the second substrate 200. In a plan view illustrated in FIG. 2, the sealing portion 350 may be formed to have a closed-loop shape along a circumference (or edge) of the display area DA. The sealing portion 350 may include an organic material such as a photocurable resin or a photoplastic resin, or may include an inorganic material such as a frit seal, but the invention is not limited thereto.

The display panel 300 may display an image in a direction from the first substrate 100 toward the second substrate 200, e.g., a light emission direction or image display direction toward the third direction DR3 in FIG. 1.

Referring to FIG. 1 and FIG. 2, the second substrate 200 has a larger area (e.g., planar area) than that of the first substrate 100 in a plan view, and has an edge positioned outside an edge of the first substrate 100. That is, the second substrate 200 extends further than the edge of the first substrate 100 to define the edge positioned outside the first substrate 100. Referring to FIG. 2, the edge of the second substrate 200 may have a closed curve shape extending along a circumstance of the first substrate 100.

Specifically, the second substrate 200 includes a first portion 210 overlapping (or corresponding to) the first substrate 100 in the third direction DR3, and a second portion 220 not overlapping the first substrate 100. As ‘not overlapping,’ an element may be adjacent to another element and/or spaced apart from the other element, without being limited thereto. The first portion 210 and the second portion 220 together form an entirety of the second substrate 200 in the form of one single plate.

The second portion 220 may be positioned outside the first portion 210, that is, further from the display area DA than the first portion 210 (or closer to an outer edge of the second substrate 200 than the first portion 210. The second portion 220 may extend along the circumference of the first substrate 100 in a donut shape, e.g., in the closed curve shape.

A thickness of the second substrate 200 in the third direction DR3 may be greater than or equal to a thickness of the first substrate 100 in the third direction DR3. For example, the thickness of the first substrate 100 in the third direction DR3 may be about 0.4 millimeter (mm), and the thickness of the second substrate 200 in the third direction DR3 may be greater than or equal to about 0.4 mm and smaller than or equal to about 0.9 mm.

The case member 400 is positioned under the display panel 300 to accommodate the display panel 300. The case member 400 may face the display panel 300, both at the display area DA and a non-display area which is adjacent to (or outside of) the display area DA. Along the plane defined by the first direction DR1 and the second direction DR2 which cross each other, the case member 400 may extend further than the display panel in the first direction DR1 and/or the second direction DR2.

The case member 400 may include a bottom portion 410 positioned at a rear side of the first substrate 100, and a first side portion 420 forming a side portion of the case member 400. The bottom portion 410 and the first side portion 420 may be integrally formed.

A cushion portion 600 may be positioned between the bottom portion 410 and the display panel 300. The cushion portion 600 may have elasticity. An adhesive layer 51 may be positioned between the cushion portion 600 and the first substrate 100, to couple the cushion portion 600 to the first substrate 100.

An adhesive member 510 and a spacer 520 may be positioned between the cushion portion 600 and the bottom portion 410. The adhesive member 510 may be an adhesive tape, and may fix the cushion portion 600 and the bottom portion 410 to each other by bonding them to each other.

The spacer 520 is spaced apart from the adhesive member 510, and may maintain a distance between the cushion portion 600 and the bottom portion 410 at a portion where the adhesive member 510 is not positioned. The spacer 520 may be positioned outside the adhesive member 510, but the invention is not limited thereto.

At least one of the adhesive member 510 and the spacer 520 may be omitted.

The first side portion 420 may have a shape protruding from an edge of the bottom portion 410 and in the third direction DR3 (e.g., toward the display panel 300).

Referring to FIG. 1, an outer portion of the second portion 220 of the second substrate 200 (e.g., extended portion) overlaps an upper surface of the first side portion 420 of the case member 400. That is, at least a portion of the second portion 220 corresponding to an edge portion of the second substrate 200 is positioned on an upper surface of the first side portion 420 of the case member 400, and overlaps the first side portion 420 when viewed in the third direction DR3.

An adhesive member 530 (e.g., first adhesive member) may be positioned between the upper surface of the first side portion 420 of the case member 400 and a lower surface of the second substrate 200. The adhesive member 530 may be an adhesive tape, and may fix the first side portion 420 and the second substrate 200 of the case member 400 to each other by bonding them to each other. The adhesive member 530 may also seal an inner space or inside of the display device, which is defined between the case member 400 and various other components or layers such as the display panel 300, the cushion portion 600, the spacer 520 and/or the adhesive member 510, etc., to obviate a window member on the second substrate 200.

An edge (e.g., an outer edge or outer side surface) of the first substrate 100 may face a side surface (e.g., an inner side surface) of the first side portion 420.

The case member 400 may further include a second side portion 430 protruding further upward from an edge of the first side portion 420 in the third direction DR3. The bottom portion 410, the first side portion 420, and the second side portion 430 may be integrally formed together.

The second side portion 430 is positioned more outward than the first side portion 420, such as with respect to the first substrate 100 and/or the display area DA. An upper surface of the second side portion 430 is higher than an upper surface of the first side portion 420, with respect to a reference, such as an upper surface of the bottom portion 410. The upper surface of the bottom portion 410 may include a virtual line extended from under the second substrate 200 and to an end (or side surface) of the case member 400 which is furthest from the display area DA. A height or thickness of each of the first side portion 420 and the second side portion 430 may be taken from this virtual line. The upper surface of the first side portion 420, the upper surface of the second side portion 430, and side portions thereof respectively facing the display panel 300 may form a step shape together. The first side portion 420 and the second side portion 430 may be coplanar with the display panel 300, such as coplanar with the first substrate 100 and/or the second substrate 200.

The second substrate 200 does not overlap the second side portion 430 in a plan view. The second side portion 430 may have a side surface that is adjacent to and faces the side surface (e.g., end side surface) of the second substrate 200. The second side portion 430 and the second substrate 200 may be spaced apart as illustrated in FIG. 1, or may be substantially adjacent to each other. The adhesive member 530 may be exposed to outside the display panel 300 (or the display device) at the space between the second side portion 430 and the second substrate 200.

Referring to FIG. 2, portions of the case member 400 which are positioned outside the edge of the second substrate 200 in a plan view may mostly include the second side portion 430, and may further include a portion of an outer edge portion of the first side portion 420 which is adjacent to (e.g., closest to) the second side portion 430.

In the plan view illustrated in FIG. 2, the case member 400 may include a portion that is positioned around the edge of the second substrate 200 and forms a closed curve. This portion may include the second side portion 430 of the case member 400.

Referring to FIG. 2, in a plan view, an innermost edge of the display area DA may be defined, an edge of the first substrate 100 may be positioned outside the innermost edge of the display area DA, an edge of the second substrate 200 may be positioned outside the innermost edge of the display area DA, and an edge of the case member 400 may be positioned outside the innermost edge of the display area DA.

A space may be positioned (or defined) between the first substrate 100 of the display panel 300, and the first side portion 420 of the case member 400. That is, the first substrate 100 may be spaced apart from the first side portion 420 in a plan view.

In the present embodiment, the second substrate 200 may be fixed to the upper surface of the first side portion 420 of the case member 400 through the adhesive member 530, and as a result, the display panel 300 may be fixedly coupled to the case member 400. In a final display device product, the case member 400 and the second substrate 200 may together form an exterior of the product.

According to the present embodiment, the case member 400 and the display panel 300 may be coupled to each other within a sealing structure to seal the inside space defined within the display device, without adding a window member in the form of a substrate made of glass or the like on the second substrate 200. Accordingly, a thickness of the display device in the third direction DR3 may be reduced, a structure of the display device may be simplified, and durability of the display device may be improved.

In order to further improve durability of the display device, according to an embodiment, the thickness of the second substrate 200 in the third direction DR3 may be greater than the thickness of the first substrate 100 in the third direction DR3. For example, the thickness of the first substrate 100 in the third direction DR3 may be about 0.4 mm, and the thickness of the second substrate 200 in the third direction DR3 may be greater than or equal to about 0.7 mm and smaller than or equal to about 0.9 mm.

Referring to FIG. 1 and FIG. 2, a polarizer 700 may be further positioned on the upper surface of the display panel 300, e.g., on the upper surface of the second substrate 200. The polarizer 700 may serve to reduce external light reflection. The polarizer 700 may be in the form of a polarizing film, but the invention is not limited thereto. The polarizer 700 may include at least one polarization layer and at least one retardation layer. The polarization layer may include polyvinyl alcohol (PVA), and may further include at least one supporter. For example, the polarizer 700 may be a circular polarization film, and in this case, the polarizer 700 may include a linear polarization layer and a quarter wave retardation layer.

The polarizer 700 may include a portion overlapping the first substrate 100, and may further include a portion overlapping the second substrate 200. That is, most regions of the first portion 210 of the first substrate 100 and the second substrate 200 in a plan view overlap the polarizer 700, and an edge portion of the polarizer 700 may include a portion overlapping the second portion 220 of the second substrate 200 in a plan view.

FIG. 1 and FIG. 2 illustrate a structure in which the polarizer 700 extends substantially to an end of the upper surface of the second substrate 200 as an example. The polarizer 700 may have an edge (e.g., an outer edge) that is spaced apart from an edge (e.g., an outer edge) of the second substrate 200 as illustrated in FIG. 1, or alternatively, the polarizer 700 may be positioned to extend to the edge of the second substrate 200 to be aligned with or coplanar therewith. According to an embodiment, the edge of the polarizer 700 may be aligned with the edge (e.g., an outer edge) of the first substrate 100.

When the display device according to an embodiment includes the polarizer 700, the polarizer 700 may form an upper surface of the completed display device, such as to define an outermost surface of the display device. As used herein, the display panel 300 may also be considered as including the polarizer 700, along with the first substrate 100 and the second substrate 200, where the display panel 300 as including the polarizer 700, may form an outermost surface of the display device.

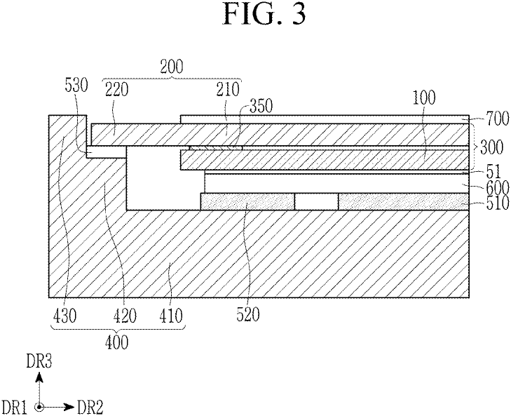

A display device according to an embodiment will be described with reference to FIG. 3 to FIG. 7 together with FIG. 1 and FIG. 2 described above.

FIG. 3 to FIG. 7 each illustrate a cross-sectional view of a display device according to an embodiment.

Referring to FIG. 3, the display device according to the present embodiment is mostly the same as the display device according to the embodiment illustrated in FIG. 1 and FIG. 2 described above, but the polarizer 700 may overlap only the first substrate 100 and the first portion 210 of the second substrate 200 in the third direction DR3, and may not overlap the second portion 220 of the second substrate 200. That is, the edge of the polarizer 700 may be substantially aligned with the edge of the first substrate 100. Outer side surfaces of the polarizer 700 and the first substrate 100 which are furthest from the display area DA, may be coplanar with each other, without being limited thereto.

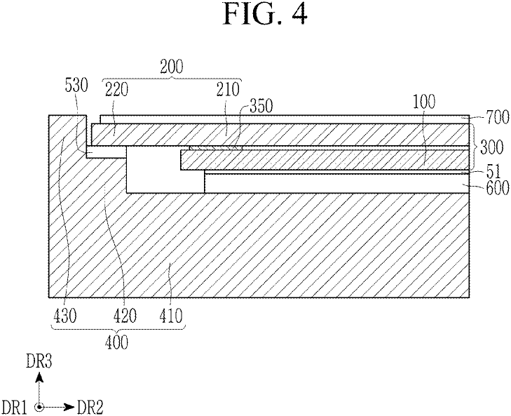

Referring to FIG. 4, the display device according to an embodiment is mostly the same as the display device according to the embodiment illustrated in FIG. 1, FIG. 2, or FIG. 3 described above, but the adhesive member 510 and the spacer 520 between the cushion portion 600 and the bottom portion 410 may be omitted. Accordingly, the cushion portion 600 may be positioned directly on the bottom portion 410. As being ‘directly on’ each other, elements may for an interface therebetween, without being limited thereto. According to an embodiment, an adhesive pattern or layer may be positioned between the cushion portion 600 and the bottom portion 410. Accordingly, an overall thickness of the display device in the third direction DR3 may be further reduced by omission of a layer including the adhesive member 510 together with the spacer 520. Since the adhesive member 530 is positioned between the lower surface of the second substrate 200 and the upper surface of the first side portion 420 of the case member 400, the display panel 300 may be fixed to the case member 400.

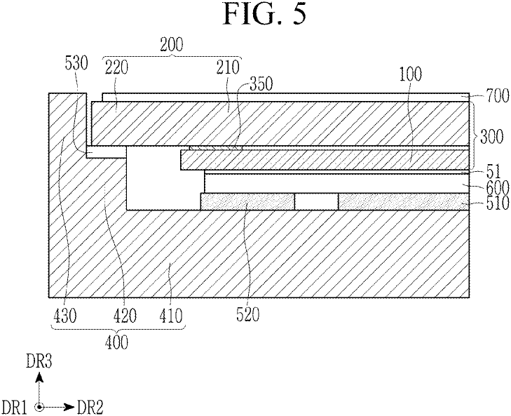

Referring to FIG. 5, the display device according to an embodiment is mostly the same as the display device according to the embodiment illustrated in FIG. 1 and FIG. 2, FIG. 3, or FIG. 4 described above, but the thickness of the second substrate 200 in the third direction DR3 may be further expanded. The thickness of the second substrate 200 is greater than the thickness of the first substrate 100, and more specifically, may be twice or more than the thickness of the first substrate 100. Accordingly, except for the polarizer 700, the thickness of the second substrate 200, which forms an actual exterior of the display device, becomes thicker, and durability of the display device may be further improved. Even in this case, since there is no need to dispose a separate window member on the second substrate 200, it is possible to maintain an overall slim thickness compared to a conventional display device including the window member.

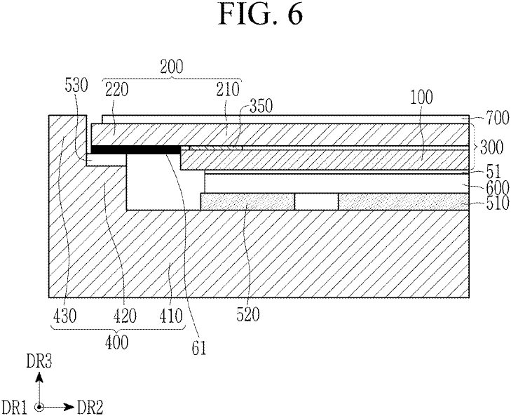

Referring to FIG. 6, the display device according to an embodiment is mostly the same as the display device according to the above-described embodiment, but a printed layer 61 (e.g., printed pattern) may be positioned on a rear surface of the edge of the second substrate 200. The printed layer 61 may overlap the upper surface of the first side portion 420 of the case member 400 and may not overlap the sealing portion 350.

The printed layer 61 may form a non-transmissive area of the second substrate 200, and may prevent a configuration positioned on the rear surface of the second substrate 200 from being visually recognized from the outside.

The printed layer 61 may be black or white, but the invention is not limited thereto, and may have various colors such as chromatic colors or metallic colors. The printed layer 61 may have a light blocking function (e.g., light blocking pattern).

The printed layer 61 may be formed (or provided) on the rear surface of the second substrate 200 by various methods such as spraying, deposition, coating, and printing.

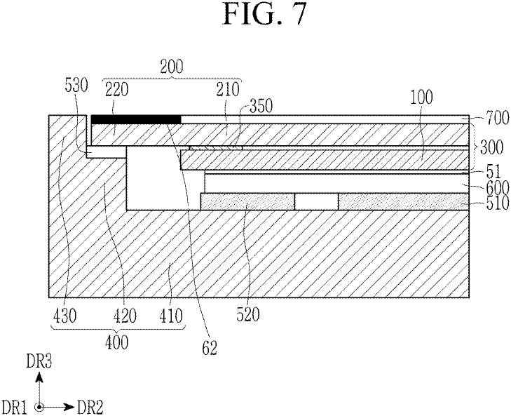

Referring to FIG. 7, the display device according to an embodiment is mostly the same as the display device according to the above-described embodiment, but a printed layer 62 may be positioned on an upper surface of the edge of the second substrate 200. The printed layer 62 may overlap an upper surface of the first side portion 420 of the case member 400. The printed layer 62 may not overlap the sealing portion 350. The printed layer 62 may further extend inward of the display panel 300 to overlap the sealing portion 350. The printed layer 62 may not overlap the polarizer 700.

In addition, the printed layer 62 may have the same characteristics as those of the printed layer 61 described above. The printed layer 62 may form an actual exterior of the display device, together with portions of the case member 400, the display panel 300 and/or the polarizer 700.

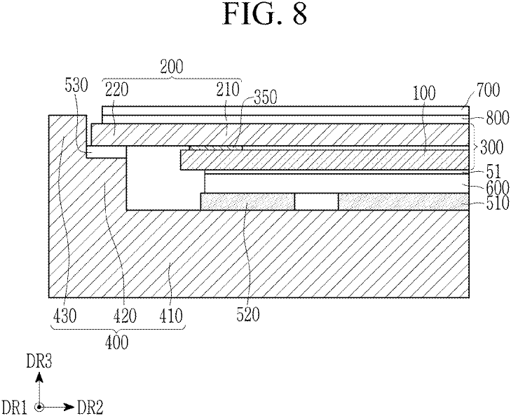

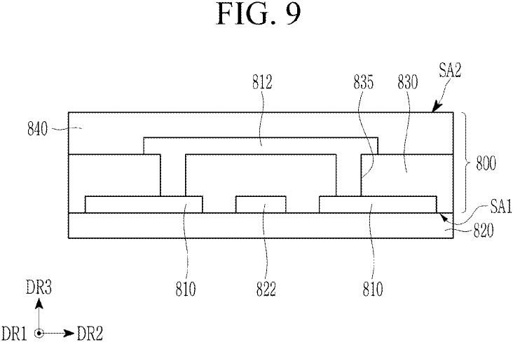

Next, a display device according to an embodiment will be described with reference to FIG. 8 and FIG. 9.

FIG. 8 illustrates a cross-sectional view of a display device according to an embodiment, and FIG. 9 illustrates a cross-sectional view of a sensor layer included in a display device according to an embodiment.

Referring to FIG. 8 and FIG. 9, the display device according to an embodiment is mostly the same as the display device according to the above-described embodiment, but may further include a sensor layer 800. The sensor layer 800 may be positioned on the display panel 300, and may be positioned between the polarizer 700 and the display panel 300. As used herein, the display panel 300 may also be considered as including the polarizer 700 and the sensor layer 800, along with the first substrate 100 and the second substrate 200, where the display panel 300 as including the polarizer 700 and the sensor layer 800, may form an outermost surface of the display device. According to an embodiment, the sensor layer 800 may be positioned on the polarizer 700 to face the display panel 300 with the polarizer 700 therebetween. An adhesive layer may be further positioned between the sensor layer 800 and the polarizer 700. The adhesive layer includes an organic polymer material, and may be of a thermosetting type or an ultraviolet (UV) curing type, but the invention is not limited thereto.

An edge (or end surface) of the sensor layer 800 may coincide with an edge (or end surface) of the polarizer 700 as illustrated in FIG. 8, such as to be aligned and/or coplanar with each other. In an embodiment, the edge of the sensor layer 800 may be positioned between an edge of the polarizer 700 and an edge of the second substrate 200 of the display panel 300, or may coincide with the edge of the second substrate 200 of the display panel 300.

FIG. 9 illustrates an example of a cross-sectional structure of the sensor layer 800. Referring to FIG. 9, the sensor layer 800 may include a plurality of touch electrodes 810. The touch electrodes 810 may include a plurality of first touch electrodes 810 and a plurality of second touch electrodes (not illustrated).

The first touch electrodes 810 and the second touch electrodes are alternately distributed along the sensor layer 800 so as to not overlap each other in a plan view in which the first direction DR1 and the second direction DR2 are extended. The first touch electrodes 810 and the second touch electrodes may be positioned on a same layer as each other, in a cross-sectional view. As being ‘on a same layer,’ elements may be formed (or provided) in a same process and/or as including a same material, elements may be in a same layer as each other as respective portions of a same material layer, may be on a same layer by forming an interface with a same underlying or overlying layer, etc., without being limited thereto.

Referring to FIG. 9, the first touch electrodes 810 arranged in a second direction DR2 in a plan view may be connected to each other through a first connector 812, and the second touch electrodes arranged in a first direction DR1 crossing the second direction DR2 may be connected to each other through a second connector 822. The second connector 822 may be positioned on a same layer as those of the first touch electrode 810 and the second touch electrode. The first connector 812 may be positioned on a different layer from those of the first touch electrode 810 and the second touch electrode. According to an embodiment, the first connector 812 may be positioned on the same layer as those of the first touch electrode 810 and the second touch electrode, and the second connector 822 may be positioned on a different layer from those of the first touch electrode 810 and the second touch electrode.

A first insulating layer 830 may be positioned between the first connector 812 and the second connector 822 to insulate the first connector 812 and the second connector 822 from each other. The first insulating layer 830 may have (or define) a contact hole 835 exposing each of the first touch electrodes 810 adjacent thereto to outside the first insulating layer 830, such that the first connector 812 can be connected to the first touch electrode 810.

The first touch electrodes 810 and the second touch electrodes may have transmittance to light (e.g., light transmittance) that is greater than or equal to a predetermined level such that light can pass therethrough. For example, the first touch electrode 810 and the second touch electrode may be made of (or include) a transparent conductive material such as an indium tin oxide (ITO), an indium zinc oxide (IZO), a thin metal layer such as silver nanowire (AgNw), a metal mesh, a carbon nanotube (CNT), or a conductive polymer.

The first touch electrode 810 and the second touch electrode adjacent to each other may form a mutual-sensing capacitor functioning as a sensor of the sensor layer 800. According to an embodiment, each of the plurality of first touch electrodes 810 and the plurality of second touch electrodes may be connected to a touch wire (not illustrated) to form a self-sensing capacitor. In this case, at least one of the first connector 812 and the second connector 822 may be omitted.

The sensor layer 800 may further include a second insulating layer 840 positioned on the first connector 812.

In FIG. 9, when a lower surface of the sensor layer 800 is referred to as a first surface SA1 and an upper surface thereof is referred to as a second surface SA2, the display panel 300 may be positioned under the first surface SA1 and the polarizer 700 may be positioned above the second surface SA2. An adhesive pattern or layer may be further positioned between the second surface SA2 and the polarizer 700.

A third insulating layer 820 may be further positioned under the first surface SA1 of the sensor layer 800. The third insulating layer 820 may be a separation layer. The third insulating layer 820 may include a polymer organic material such as a polyimide, a polyvinyl alcohol, a polyamic acid, a polyamide, a polyethylene, a polystylene, etc. The third insulating layer 820 may further include an adhesive layer.

Unlike in FIG. 9, upper and lower portions of the sensor layer 800 may be in an upside-down state within the display device. That is, the first surface SA1 of the sensor layer 800 may be positioned to face upward, and the second surface SA2 may be positioned to face the display panel 300.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a display panel including a display area, a first substrate including a transistor in the display area, and a second substrate facing the first substrate; and
a case member in which the display panel is accommodated, the case member including:
a bottom portion facing the first substrate and the second substrate of the display panel, and
a first side portion protruding from the bottom portion and toward the display panel,
wherein the second substrate includes:
a first portion corresponding to the first substrate, and
a second portion extended from the first portion to overlap the first side portion of the case member.

2. The display device of claim 1, wherein the display panel further includes:
the first substrate further including a light emitting device in the display area, a sealing portion between the first substrate and the second substrate, and
the second substrate and the sealing portion seal the light emitting device.

3. The display device of claim 1, wherein
each of the first substrate and the second substrate has an edge furthest from the display area in a direction, and
the edge of the second substrate is further from the display area than the edge of the first substrate, in the direction.

4. The display device of claim 1, wherein
the second substrate is further from the bottom portion of the case member than the first substrate, and
a thickness of the second substrate is equal to or greater than a thickness of the first substrate.

5. The display device of claim 4, wherein
the first substrate and the second substrate include glass.

6. The display device of claim 1, further comprising
a first adhesive member between the first side portion of the case member and the second portion of the second substrate which overlaps the first side portion of the case member.

7. The display device of claim 1, wherein
the case member further includes a second side portion which protrudes from the first side portion and extends further from the bottom portion than the first side portion, and
the first side portion which overlaps the second substrate is between the second side portion and the first substrate.

8. The display device of claim 7, wherein
the second substrate has a side surface furthest from the display area in a direction, and
the second side portion of the case member faces the side surface of the second substrate, in the direction.

9. The display device of claim 1, further comprising
a polarizer facing the first substrate and the first portion of the second substrate.

10. The display device of claim 9, wherein
each of the first substrate and the polarizer has an edge furthest from the display area in a direction, and
the edge of the polarizer is aligned with the edge of the first substrate.

11. The display device of claim 1, further comprising
a light blocking pattern corresponding to an edge of the second substrate which overlaps the first side portion of the case member.

12. The display device of claim 11, further comprising
a sealing portion which is between the first substrate and the second substrate and seals the transistor,
wherein the light blocking pattern is coplanar with the sealing portion and the first substrate.

13. The display device of claim 11, further comprising
a polarizer facing the first substrate with the second substrate therebetween,
wherein the light blocking pattern is coplanar with the polarizer.

14. A display device comprising:
a first substrate including a display element;
a second substrate facing the first substrate; and
a case member including:
a bottom portion facing the first substrate and the second substrate of the display panel, and
a first side portion protruding from the bottom,
wherein the second substrate faces the bottom portion of the case member with the first side portion therebetween and is fixed to the case member at the first side portion.

15. The display device of claim 14, wherein
each of the first substrate and the second substrate has an edge furthest from the display element in a direction, and
the edge of the second substrate is further from the display element than the edge of the first substrate, in the direction.

16. The display device of claim 14, wherein
the second substrate is further from the bottom portion of the case member than the first substrate, and
a thickness of the second substrate is equal to or greater than a thickness of the first substrate.

17. The display device of claim 14, wherein
the case member further includes a second side portion which protrudes from the first side portion and extends further from the bottom portion than the first side portion, and
the second substrate is coplanar with the second side portion of the case member.

18. The display device of claim 14, further comprising
a polarizer facing the first substrate and the first portion of the second substrate.

19. The display device of claim 18, further comprising
a light blocking pattern corresponding to an edge of the second substrate which faces the first side portion of the case member.

20. A display device comprising:
a case member including a bottom portion and a side portion; and
a display panel including a first substrate, a second substrate and a polarizer in order from the bottom portion,
wherein in a direction along the bottom portion of the case member:
the first substrate is spaced apart from the side portion, and
the second substrate overlaps the side portion.
